(19) United States
(12) Patent Application Publication
(10) Pub. No.: US 2026/0371538 A1
(43) Pub. Date: Nov. 19, 2026

(54) BUSBAR AND SERVER SYSTEM

(71) Applicant: Wiwynn Corporation, New Taipei City (TW)

(72) Inventors: Hao-Jhan Hong, New Taipei City (TW); CHIA-HSING HSIEH, New Taipei City (TW)

(21) Appl. No.: 19/674,278

(22) Filed: May 12, 2026

Related U.S. Application Data
(60) Provisional application No. 63/805,976, filed on May 14, 2025.
(60) Provisional application No. 63/873,223, filed on Aug. 29, 2025.

(30) Foreign Application Priority Data
Mar. 13, 2026 (TW) 115109426

(51) Int. Cl. H05K 7/20; H05K 7/14

(52) U.S. Cl. CPC H05K 7/20927; H05K 7/1492; H05K 7/20263; H05K 7/20272; H05K 7/20781

(57) ABSTRACT

A server system includes a server rack and a busbar. The server rack includes a rack, at least one server and at least one power module group, and the server and the power module group are accommodated in the rack. The busbar is electrically connected to the server and the power module group. The busbar includes a casing, an electrode set and at least one flow structure. The electrode set is disposed in the casing. The flow structure is disposed in the casing and thermally coupled to the electrode set. The flow structure is provided with a heat exchange channel, the heat exchange channel includes at least one heat exchange section and at least one transition section in fluid communication with each other, and a surface area-to-volume ratio of the heat exchange section is greater than a surface area-to-volume ratio of the transition section.

### CROSS-REFERENCE TO RELATED APPLICATIONS

This non-provisional application claims priority under 35 U.S.C. § 119(a) on Provisional Application No(s). 63/805,976 filed in U.S.A. on May 14, 2025, Provisional Application No(s). 63/873,223 filed in U.S.A. on Aug. 29, 2025, and Patent Application No(s). 115109426 filed in Taiwan, R.O.C. on Mar. 13, 2026, the entire contents of which are hereby incorporated by reference.

### TECHNICAL FIELD

The disclosure relates to a busbar and a server system.

### BACKGROUND

With the overall power of server racks increasing, conventional air-cooling methods are insufficient to dissipate heat from servers in the server racks. Therefore, most server racks currently employ liquid-cooling systems for heat dissipation. In configurations that rely entirely on liquid cooling, no airflow is driven by fans through the busbar, making it difficult for the busbar to release heat. As a result, busbars capable of being cooled by liquid have been developed, which receive a conductive coolant in a liquid cooling loop formed by the liquid cooling system and the servers.

However, current flow structure designs in busbars may results in excessively high pressure drop of the coolant, and thus fails to balance the required heat dissipation performance and reduction of pressure drop. In view of the above, there remains a need in the art to address the aforementioned issues.

### SUMMARY

One embodiment of the disclosure provides a server system. The server system includes a server rack and a busbar. The server rack includes a rack, at least one server and at least one power module group, and the server and the power module group are accommodated in the rack. The busbar is electrically connected to the server and the power module group. The busbar includes a casing, an electrode set and at least one flow structure. The electrode set is disposed in the casing. The flow structure is disposed in the casing and thermally coupled to the electrode set. The flow structure is provided with a heat exchange channel, the heat exchange channel includes at least one heat exchange section and at least one transition section in fluid communication with each other, and a surface area-to-volume ratio of the heat exchange section is greater than a surface area-to-volume ratio of the transition section.

Another embodiment of the disclosure provides a busbar. The busbar includes a casing, an electrode set and at least one flow structure. The electrode set is disposed in the casing. The flow structure is disposed in the casing and thermally coupled to the electrode set. The flow structure is provided with a heat exchange channel, the heat exchange channel includes at least one heat exchange section and at least one transition section in fluid communication with each other, and a surface area-to-volume ratio of the heat exchange section is greater than a surface area-to-volume ratio of the transition section.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a rear view of a server system according to some embodiments of the disclosure;

FIG. 2 is a block diagram of a server system according to some embodiments of the disclosure;

FIG. 3 is a perspective view of a busbar according to some embodiments of the disclosure;

FIG. 4 is an exploded view of a busbar according to some embodiments of the disclosure;

FIG. 5 is a side view of a busbar according to some embodiments of the disclosure;

FIG. 6 is a partially enlarged side view of a busbar according to some embodiments of the disclosure;

FIGS. 7 to 9 are cross-sectional views of a busbar according to some embodiments of the disclosure;

FIG. 10 is a rear view of a server system according to some embodiments of the disclosure;

FIG. 11 is a rear view of a server system according to some embodiments of the disclosure;

FIG. 12 is a rear view of a server system according to some embodiments of the disclosure;

FIG. 13 is a rear view of a server system according to some embodiments of the disclosure;

FIG. 14 is a block diagram of a server system according to some embodiments of the disclosure;

FIG. 15 is a block diagram of a server system according to some embodiments of the disclosure;

FIGS. 16 to 18 are cross-sectional views of a busbar according to some embodiments of the disclosure;

FIGS. 19 to 21 are cross-sectional views of a busbar according to some embodiments of the disclosure; and

FIG. 22 is a block diagram of a server system according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

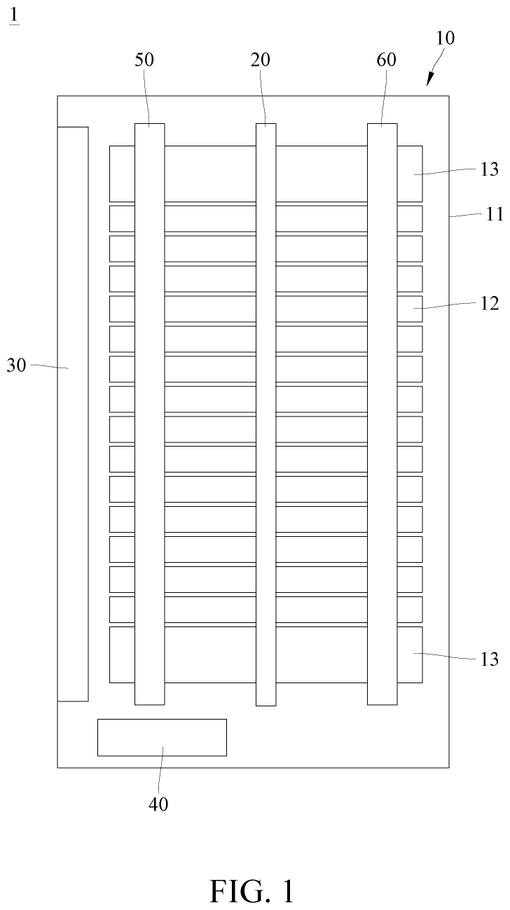

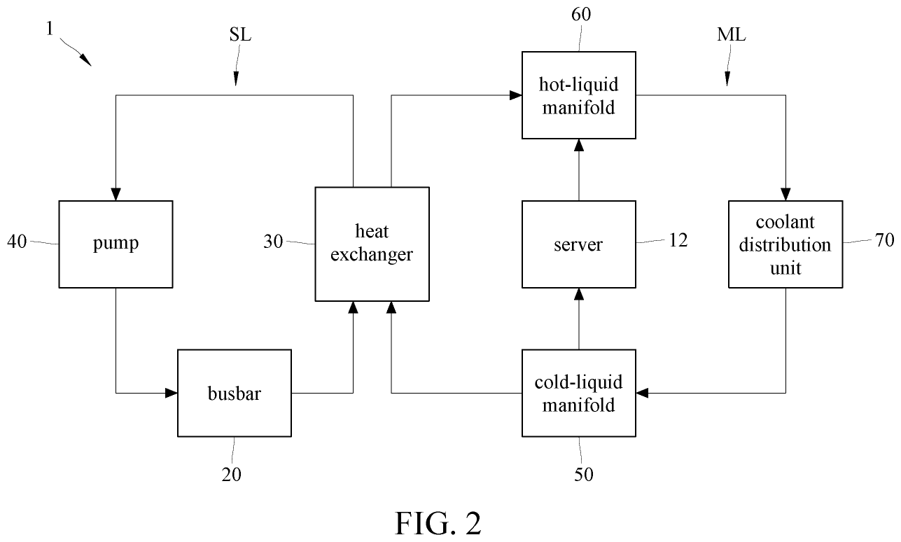

Referring to FIGS. 1 and 2, FIG. 1 is a rear view of a server system 1 according to some embodiments of the disclosure, and FIG. 2 is the block diagram of a server system 1 according to some embodiments of the disclosure. In FIG. 2, an arrow between two components represents that the two components are in fluid communication via a pipeline and indicates a flow direction of a coolant in the pipeline. The structural features of FIGS. 1 and 2 may be applied to some other embodiments of the disclosure.

The server system 1 includes a server rack 10 and a busbar 20. The server rack 10 includes a rack 11, at least one server 12 and at least one power module group 13. The busbar 20 is electrically connected to the server 12 and the power module group 13 to deliver power from the power module group 13 to the server 12.

In some embodiments, the server system may include a plurality of servers 12 and two power module groups 13. The servers 12 are arranged horizontally along a direction from a top to a bottom of the rack 11. The servers 12 are located between the two power module groups 13, and the two power module groups 13 are respectively located adjacent to the top and the bottom of the rack 11. The two power module groups 13 are connected to the busbar 20 at two locations respectively adjacent to the top and the bottom of the rack 11, such that heat concentration regions are formed at these two locations. Each of the power module groups 13 includes one or more power shelves, and each power shelf includes a plurality of power supply units (PSUs) and associated peripheral hardware.

In some embodiments, the server system 1 may further include a heat exchanger 30 and a pump 40. The pump 40, the busbar 20 and the heat exchanger 30 together form a secondary cooling loop SL for conveying a first coolant (not shown). The pump 40 is configured to drive the first coolant such that the first coolant is circulated through the secondary cooling loop SL. When the first coolant flows into the busbar 20, the first coolant absorbs heat generated by power transmission in the busbar 20 and is heated, thereby cooling the busbar 20. After leaving the busbar 20, the first coolant enters the heat exchanger 30 and is cooled, where the detailed cooling process of the first coolant in the heat exchanger 30 will be described later. The cooled first coolant then returns to the pump 40.

In some embodiments, the heat exchanger 30 is disposed at a rear side of the rack 11. For example, the heat exchanger 30 may be disposed at the rear side of one of side walls of the rack 11.

In some embodiments, the server system 1 may further include a cold-liquid manifold 50, a hot-liquid manifold 60 and a coolant distribution unit 70. The coolant distribution unit 70, the cold-liquid manifold 50, the hot-liquid manifold 60 and the servers 12 together form a primary cooling loop ML for conveying a second coolant (not shown). The primary cooling loop ML is independent of the secondary cooling loop SL. That is, the primary cooling loop ML and the secondary cooling loop SL do not share any flow channels or pipelines, ensuring that the second coolant in the primary cooling loop ML does not come into contact with the first coolant in the secondary cooling loop SL.

In some embodiments, the coolant distribution unit 70 may be disposed together with the servers 12 in the rack 11, thereby forming an in-rack coolant distribution unit (In-rack CDU). Alternatively, the coolant distribution unit 70 may be disposed in another rack (not shown) adjacent to the server rack 10, thereby forming an in-row coolant distribution unit (In-row CDU).

In some embodiments, the coolant distribution unit 70 may, for example, include a pump and a radiator (both not shown). The pump of the coolant distribution unit 70 drives the second coolant to the cold-liquid manifold 50. The cold-liquid manifold 50 delivers the second coolant to the servers 12 so that the second coolant absorbs heat generated by heat sources in the servers 12 and is heated. The hot-liquid manifold 60 receives the high-temperature second coolant from the servers 12 and conveys it to the coolant distribution unit 70, where it is cooled by the radiator in the coolant distribution unit 70. The second coolant in the radiator may be cooled either by air cooling or liquid cooling. For example, airflow generated by a fan may carry away heat from the second coolant in the radiator. Alternatively, the radiator may be thermally coupled to another cooling loop (such as a facility water loop) so that the heat from the second coolant in the radiator is transferred to the coolant (e.g., facility water) in the other cooling loop and thereby cooled.

In some embodiments, the cold-liquid manifold 50 and the hot-liquid manifold 60 may be in fluid communication with the heat exchanger 30. In this way, a portion of the low-temperature second coolant in the primary cooling loop ML can flow into the heat exchanger 30, allowing the high-temperature first coolant in the secondary cooling loop SL that enters the heat exchanger 30 to exchange heat with the low-temperature second coolant. As a result, the first coolant leaving the heat exchanger 30 returns to the pump 40 in a low-temperature state, and the second coolant leaving the heat exchanger 30 returns to the hot-liquid manifold 60 (i.e., the primary cooling loop ML) in a high-temperature state.

In some embodiments, the first coolant is a dielectric liquid, and the second coolant is different from the first coolant. For example, the second coolant may be a conductive liquid, but is not limited thereto. In other embodiments, the first coolant and the second coolant may each be different types of dielectric liquids.

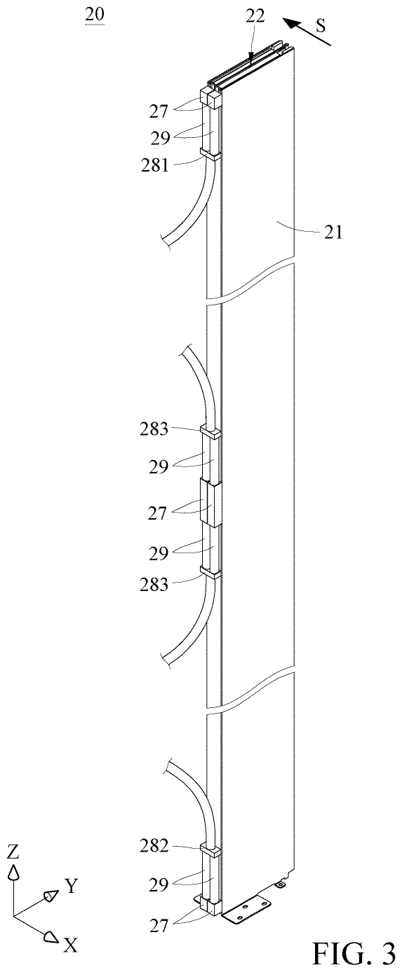

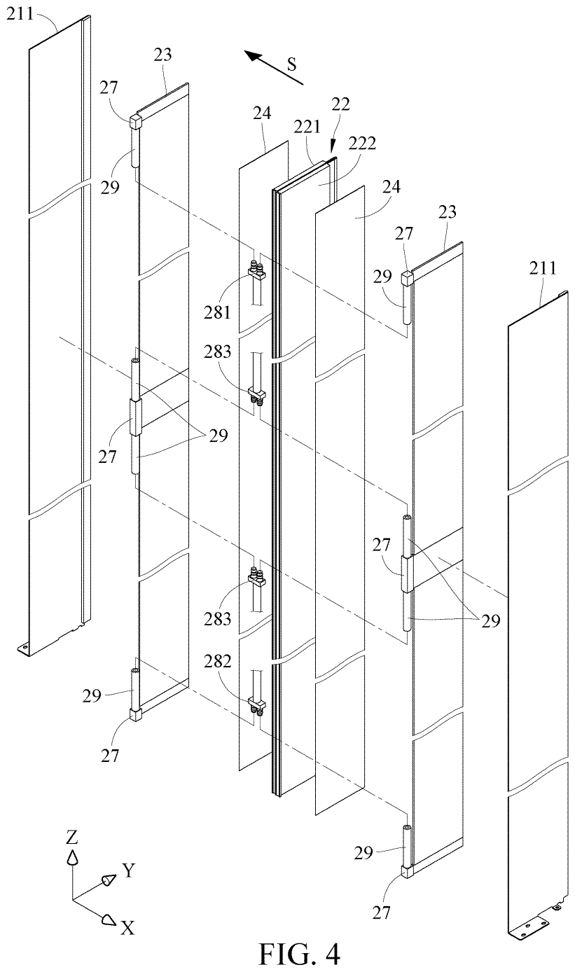

Then, referring to FIGS. 3 and 4, FIG. 3 is a perspective view of the busbar 20 according to some embodiments of the disclosure, and FIG. 4 is an exploded view of the busbar 20 according to some embodiments of the disclosure. The structural features of FIGS. 3 and 4 may be applied to some other embodiments of the disclosure.

The busbar 20 includes a casing 21, an electrode set 22 and at least one flow structure 23. The electrode set 22 is disposed in the casing 21. The flow structure 23 is disposed in the casing 21 and is thermally coupled to the electrode set 22.

In some embodiments, the electrode set 22 includes a positive electrode 221 and a negative electrode 222, and the busbar 20 includes two flow structures. The two flow structures 23 are respectively thermally coupled to the positive electrode 221 and the negative electrode 222.

In some embodiments, the busbar 20 may further include two thermally conductive insulating materials 24. The two flow structures 23 are respectively thermally coupled to the positive electrode 221 and the negative electrode 222 through the two thermally conductive insulating materials 24.

In some embodiments, the casing 21 of the busbar 20 may include two casing portions 211, which are respectively located on sides of the two flow structures 23 away from the electrode set 22. In some embodiments, the electrode set 22, the two flow structures 23 and the two casing portions 211 are all plate-shaped and together form a multilayer structure. In this way, the two casing portions 211, the two flow structures 23, the two thermally conductive insulating materials 24 and the electrode set 22 can be assembled in a simple manner. Specifically, the two thermally conductive insulating materials 24 are first respectively disposed on the positive electrode 221 and the negative electrode 222 of the electrode set 22, then the two flow structures 23 are respectively stacked on the two thermally conductive insulating materials 24, and thereafter the two casing portions 211 are stacked on the two flow structures 23 and fixed, thereby completing the assembly process.

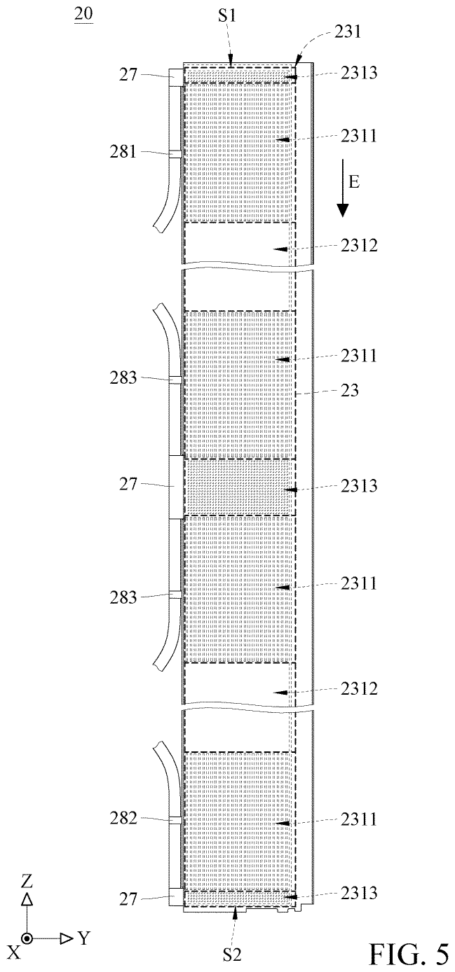

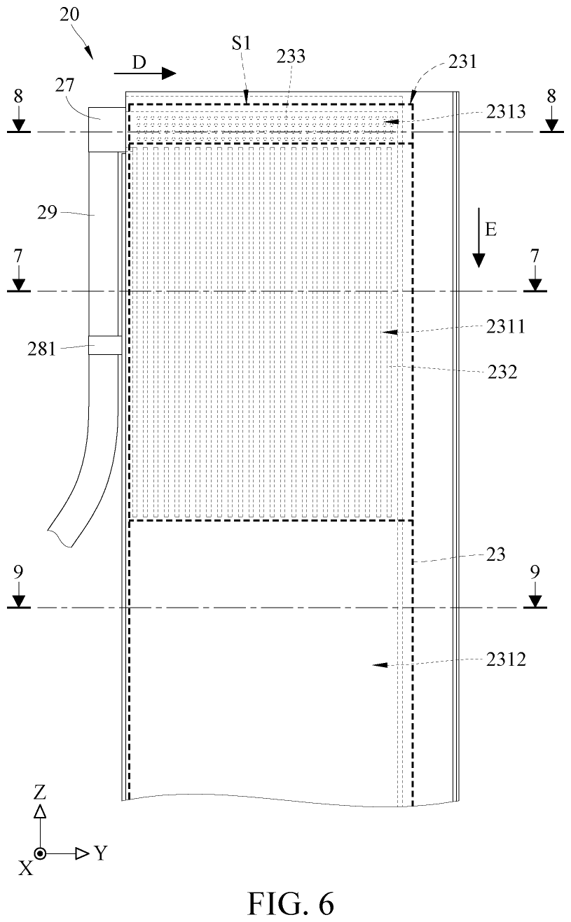

Then, referring to FIGS. 5 and 6, FIG. 5 is a side view of the busbar 20 according to some embodiments of the disclosure, and FIG. 6 is a partially enlarged side view of the busbar 20 according to some embodiments of the disclosure. The structural features of FIGS. 5 and 6 may be applied to some other embodiments of the disclosure.

In some embodiments, the two flow structures 23 have same structures; therefore, only one of them is described in detail below.

In some embodiments, the flow structure 23 is provided with a heat exchange channel 231 for conveying the above-mentioned first coolant. The flow structure 23 may, for example, be a rectangular plate shape, and an extension direction E of the heat exchange channel 231 is parallel to a long side of the flow structure 23. The heat exchange channel 231 includes at least one heat exchange section 2311 and at least one transition section 2312 in fluid communication with each other. A surface area-to-volume ratio (i.e., SAV) of the heat exchange section 2311 is greater than that of the transition section 2312. The surface area-to-volume ratio is defined as a contact surface area between the fluid and the solid in a region divided by a volume of the fluid in the region.

Then, referring to FIGS. 5 to 7, FIG. 7 is a cross-sectional view of the busbar 20 according to some embodiments of the disclosure, which is taken along a line 7-7 in FIG. 6.

In some embodiments, the flow structure 23 may be further provided with a plurality of first fins 232, and the first fins 232 are disposed only in the heat exchange section 2311 of the heat exchange channel 231.

In some embodiments, the first fins 232 are plate-shaped structures. To illustrate the surface area-to-volume ratio of the heat exchange section 2311, assuming that the first fins 232 in the heat exchange section 2311 have a thickness of 2 mm, a spacing of 2 mm, and a height of 1.5 mm, and the heat exchange section 2311 is divided into 36 channels, the surface area-to-volume ratio of the heat exchange section 2311 is calculated as follows:

$$SAV = \frac{2 \times ( 1.5 mm + 2 mm )}{2 mm \times 1.5 mm} \times 36 = 84 ( {mm}^{- 1} ) .$$

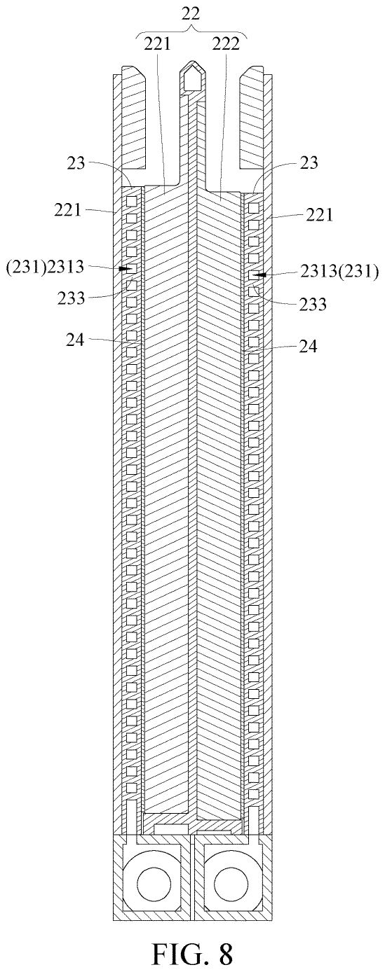

Then, referring to FIGS. 5, 6 and 8, FIG. 8 is a cross-sectional view of the busbar 20 according to some embodiments of the disclosure, which is taken along a line 8-8 in FIG. 6.

In some embodiments, the busbar 20 may further include at least one connector 27. The flow structure 23 may be further provided with a plurality of second fins 233, and the heat exchange channel 231 may further include at least one connection section 2313. The connection section 2313 is in fluid communication with the heat exchange section 2311 and the transition section 2312. The second fins 233 are disposed only in the connection section 2313 of the heat exchange channel 231, and the connector 27 is in fluid communication with the connection section 2313.

In some embodiments, the second fins 233 are pin-fin structures, and a direction D in which the connector 27 is in fluid communication with the connection section 2313 is perpendicular to an extension direction E of the first fins 232. The direction D in which the connector 27 is in fluid communication with the connection section 2313 refers to a flow direction in which the first coolant flows from the connector 27 into the connection section 2313, and is parallel to a short side of the flow structure 23, while the extension direction E of the first fins 232 is parallel to a long side of the busbar 20. Accordingly, the first coolant flows laterally from the connector 27 into the connection section 2313 and passes through the second fins 233 disposed therein, and then flows into the heat exchange section 2311 and passes through the first fins 232 disposed therein. By providing the second fins 233 (e.g., pin fin structures) in the connection section 2313, it is ensured that the first coolant laterally flowing into the connection section 2313 is not obstructed by the second fins 233 and can be uniformly guided toward the first fins 232 in the heat exchange section 2311.

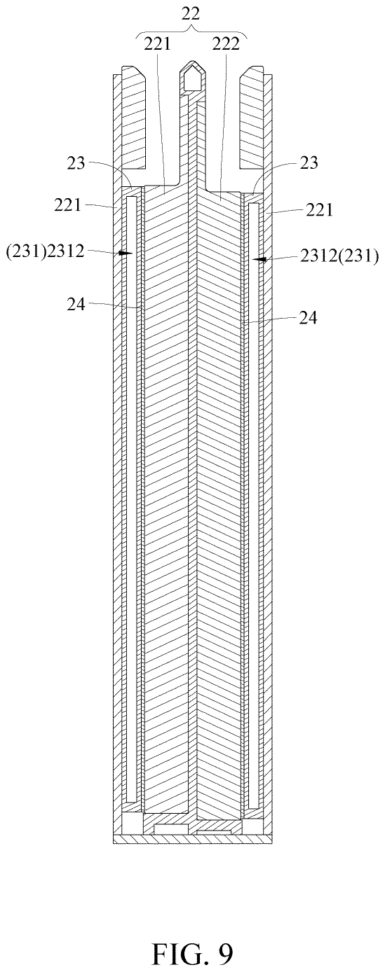

Then, referring to FIGS. 6 and 9, FIG. 9 is a cross-sectional view of the busbar 20 according to some embodiments of the disclosure, which is taken along a line 9-9 in FIG. 6. In some embodiments, no fin structures are provided in the transition section 2312 of the flow structure 23.

To illustrate the surface area-to-volume ratio of the transition section 2312, assuming that a cross-sectional area of a channel in the transition section 2312 is 142 mm×1.5 mm, the surface area-to-volume ratio of the heat exchange section 2311 is calculated as follows:

$$SAV = \frac{2 \times ( 1.5 mm + 142 mm )}{142 mm \times 1.5 mm} = 1.35 ( {mm}^{- 1} ) .$$

As shown in FIG. 5, in some embodiments, the heat exchange channel 231 may include a plurality of heat exchange sections 2311 and a plurality of connection sections 2313. The heat exchange sections 2311 are located between the connection sections 2313, and the transition sections 2312 are located between the heat exchange sections 2311. In addition, the busbar 20 may include a plurality of connectors 27, and the connectors 27 are respectively in fluid communication with the connection sections 2313.

As shown in FIG. 5, in some embodiments, the heat exchange channel 231 may include two transition sections 2312, three connection sections 2313 and four heat exchange sections 2311. Among the three connection sections 2313, two of the heat exchange sections 2311 are disposed between adjacent two of the connection sections 2313, and one of the two transition sections 2312 is disposed between the two heat exchange sections 2311. That is, along the extension direction E of the heat exchange channel 231, from one side S1 to an opposite side S2 of the heat exchange channel 231, different portions of the heat exchange channel 231 are, in sequence, the connection section 2313, the heat exchange section 2311, the transition section 2312, the heat exchange section 2311, the connection section 2313, the heat exchange section 2311, the transition section 2312, the heat exchange section 2311, and the connection section 2313. Each of the connection sections 2313 is connected to one connector 27.

In some embodiments, the opposite sides S1 and S2 of the heat exchange channel 231 are respectively located adjacent to the top and the bottom of the rack 11 (as shown in FIG. 1). Two of the four heat exchange sections 2311 and two of the three connection sections 2313, located closest to the top and the bottom of the rack 11, correspond to the two power module groups 13 in FIG. 1. That is, two of the four heat exchange sections 2311 and two of the three connection sections 2313, located closest to the top and the bottom of the rack 11, correspond to heat concentration regions.

As shown in FIGS. 3 and 4, in some embodiments, the busbar 20 may further include a plurality of T-fittings 281, 282, 283 and a plurality of connection pipes 29. The connectors 27 connected to the two flow structures 23 overlap with each other in a stacking direction S of the multilayer structure, and two of the connectors 27 that overlap with each other are respectively connected to one of the T-fittings 281, 282, 283 via two of the connection pipes 29. The T-fitting 281 is connected to the connection section 2313 located closest to the top of the rack 11, and may therefore be referred to as a top T-fitting 281. The T-fitting 282 is connected to the connection section 2313 located closest to the bottom of the rack 11, and may therefore be referred to as a bottom T-fitting 282. The T-fitting 283 is connected to the connection sections 2313 away from both the top and bottoms of the rack 11, and may therefore be referred to as a middle T-fitting 283.

It should be noted that the connection pipes 29 are an optional component and may be omitted in other embodiments. In such a case, two of the connectors overlapped with each other may be directly connected to one of the T-fittings

In some embodiments, the top T-fitting 281 and the bottom T-fitting 282 are respectively connected to the pump 40 via piping to receive low-temperature first coolant from the pump 40. Accordingly, the low-temperature first coolant entering two of the three connection sections 2313 and two of the four heat exchange sections 2311, located closest to the top and the bottom of the rack 11, can directly dissipate heat from the heat concentration regions. The middle T-fitting 283 is connected to the heat exchanger 30 via piping to deliver high-temperature first coolant exiting the busbar 20 to the heat exchanger 30 for cooling. In this way, the arrangement of the T-fittings 281, 282, 283 simplifies the piping for introducing and discharging the first coolant, thereby facilitating assembly.

It should be noted that the T-fittings 281, 282, 283 are optional components and may be omitted in other embodiments. In such a case, each connector may be connected to the heat exchanger or the pump via a single pipe.

In the above embodiments, the flow structure 23 of the busbar 20 includes the heat exchange sections 2311 and the transition sections 2312 in fluid communication with each other, and the surface area-to-volume ratio of the heat exchange sections 2311 are greater than that of the transition sections 2312. In such a configuration, regions of the flow structure 23 requiring higher heat exchange efficiency (e.g., regions corresponding to the power module groups 13) may be handled by the heat exchange sections 2311 to improve heat exchange efficiency. Meanwhile, regions of the flow structure 23 requiring lower heat exchange efficiency (e.g., regions not corresponding to the power module groups 13) may be handled by the transition sections 2312 to reduce pressure drop. Accordingly, the pressure drop in the flow structure 23 can be reduced while maintaining the required heat dissipation performance. For example, referring to Table 1, Table 1 shows simulation results under identical conditions for the busbar 20 of the above embodiments, a busbar in which the entire heat exchange channel is provided with fins, and a busbar in which the entire heat exchange channel has no fins.

TABLE 1

| | | busbar in which | |
|---|---|---|---|
| | | entire heat | busbar in which |
| | busbar 20 of | exchange channel | entire heat |
| | the above | is provided with | exchange channel |
| Type | embodiment | fins | has no fins |
| pressure drop in | 10.8 | 13 | 8 |
| flow channel of | | | |
| busbar (psi) | | | |
| temperature rise of | 24 | 20 | 28 |
| busbar (°C) | | | |

From Table 1, in a configuration in which the busbar has no fins in the entire heat exchange channel, the pressure drop in the flow channel of the busbar is the lowest, while the temperature rise of the busbar is the highest. In a configuration in which fins are provided in the entire heat exchange channel, the pressure drop in the flow channel of the busbar is the highest, while the temperature rise of the busbar is the lowest. That is, the busbar with fins throughout the entire heat exchange channel achieves the best heat dissipation performance but results in an excessively high pressure drop, whereas the busbar without fins throughout the entire heat exchange channel exhibits the opposite behavior. Although, in the configuration of the busbar 20 according to the above embodiment, both the pressure drop in the flow channel of the busbar and the temperature rise of the busbar are not the lowest, they are both below predetermined specification values. Accordingly, a balance is achieved between pressure drop and temperature rise, thereby reducing the pressure drop in the flow structure 23 while maintaining the required heat dissipation performance.

In addition, the configuration of the busbar 20 according to the above embodiment can achieve a balance between pressure drop and temperature rise. Therefore, for example, under a given pressure constraint, the heat dissipation performance may be maximized, and the flow rate of the coolant may be reduced to achieve energy savings. In addition, under a given heat dissipation performance requirement, the pressure drop may be minimized, thereby enabling the use of a non-conductive coolant with a higher viscosity to reduce the risk of leakage-induced short circuits.

It should be noted that the numbers of the heat exchange section 2311, the transition section 2312 and the connection section 2313 in the flow structure 23 are not limited to those described above, and may be adjusted according to requirements. Correspondingly, the number of the connectors 27 may also be adjusted according to the number of the connection sections 2313.

In addition, the connection sections 2313 in the flow structure 23 are optional structures and may be omitted in other embodiments. In such a case, the connectors may be directly in fluid communication with the heat exchange sections or the transition sections.

Moreover, the configuration in which the surface area-to-volume ratio of the heat exchange sections 2311 in the flow structure 23 is greater than that of the transition sections 2312 is not limited to being achieved by providing fin structures in the heat exchange sections 2311 and no fin structures in the transition sections 2312. In other embodiments, fin structures may be provided in both the heat exchange sections and the transition sections, and the above configuration may be achieved by configuring a fin density in the heat exchange sections to be greater than that in the transition sections. Alternatively, the configuration may be achieved using other structures other than fins.

The busbar 20 according to the above embodiment is not limited to being applied to the configuration of FIG. 1 in which two power module groups 13 of the server rack 10 are respectively located adjacent to the top and bottom of the rack 11. The following provides illustrative examples.

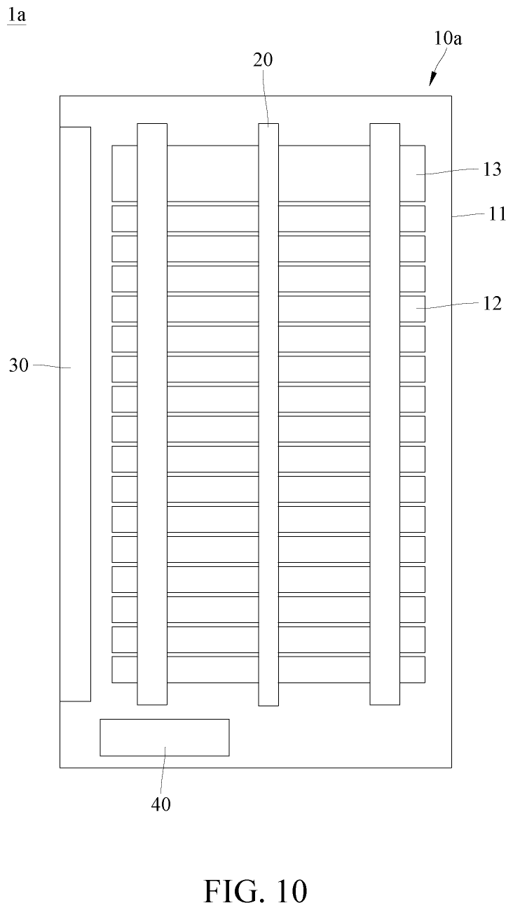

Referring to FIGS. 5 and 10, FIG. 10 is a rear view of a server system 1a according to some embodiments of the disclosure. The structural features of FIG. 10 may be applied to some other embodiments of the disclosure.

The busbar 20 according to the above embodiment may be applied to a configuration in a server rack 10a in which only one power module group 13 is provided adjacent to the top of the rack 11. The power module group 13 corresponds to the heat exchange section 2311 and the connection section 2313 that are located closest to the top of the rack 11 in the heat exchange channel 231. In such a configuration, the top T-fitting 281 may be connected to the pump 40 via piping to receive low-temperature first coolant from the pump 40. Accordingly, the low-temperature first coolant entering the connection section 2313 and the heat exchange section 2311 located closest to the top of the rack 11 can directly dissipate heat from the heat concentration region. The bottom T-fitting 282 may be connected to the heat exchanger 30 via piping to deliver high-temperature first coolant exiting the busbar 20 to the heat exchanger 30 for cooling. The middle T-fitting 283 may be sealed and not connected to other components.

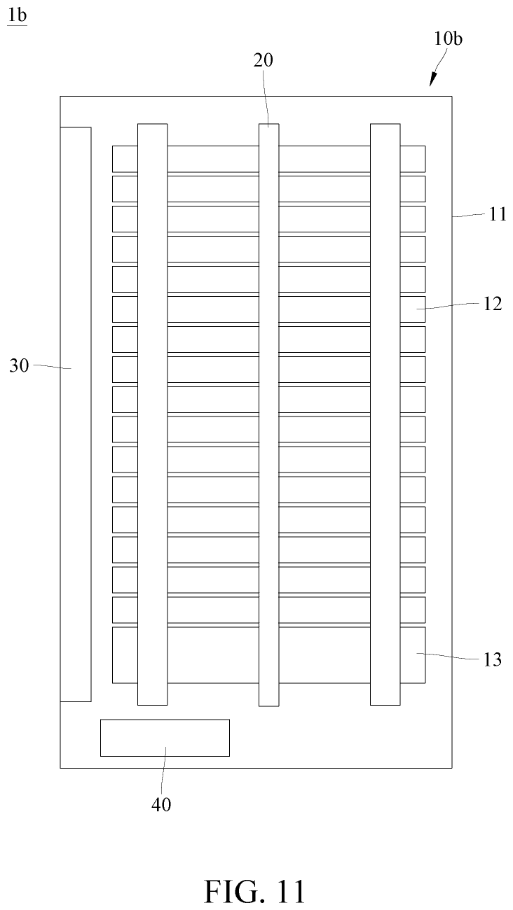

Referring to FIGS. 5 and 11, FIG. 11 is a rear view of a server system 1b according to some embodiments of the disclosure. The structural features of FIG. 11 may be applied to some other embodiments of the disclosure.

The busbar 20 according to the above embodiment may be applied to a configuration in a server rack 10b in which only one power module group 13 is provided adjacent to the bottom of the rack 11. The power module group 13 corresponds to the heat exchange section 2311 and the connection section 2313 that are located closest to the bottom of the rack 11 in the heat exchange channel 231. In such a configuration, the bottom T-fitting 282 may be connected to the pump 40 via piping to receive low-temperature first coolant from the pump 40. Accordingly, the low-temperature first coolant entering the connection section 2313 and the heat exchange section 2311 located closest to the bottom of the rack 11 can directly dissipate heat from the heat concentration region. The top T-fitting 281 may be connected to the heat exchanger 30 via piping to deliver high-temperature first coolant exiting the busbar 20 to the heat exchanger 30 for cooling. The middle T-fitting 283 may be sealed and not connected to other components.

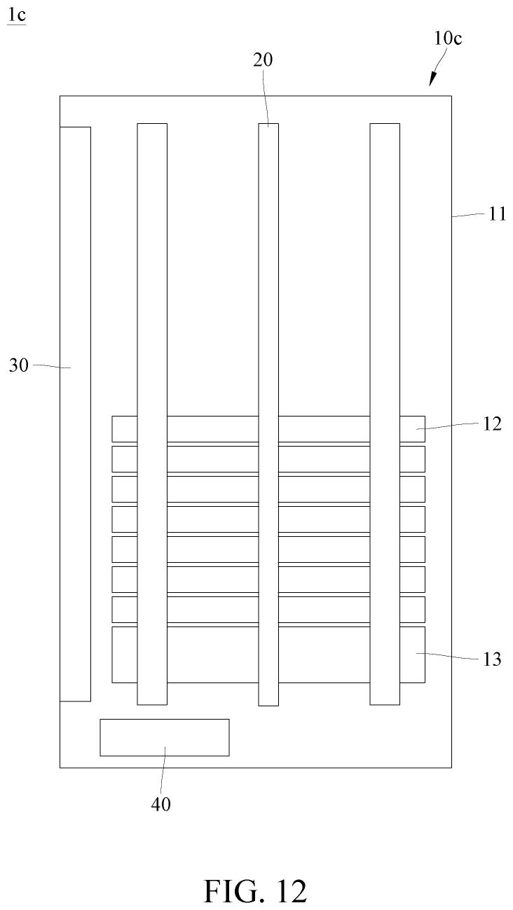

Referring to FIGS. 5 and 12, FIG. 12 is a rear view of a server system 1c according to some embodiments of the disclosure. The structural features of FIG. 12 may be applied to some other embodiments of the disclosure.

The busbar 20 according to the above embodiment may be applied to a configuration in a server rack 10c in which only one power module group 13 is provided adjacent to the bottom of the rack 11. The power module group 13 corresponds to the heat exchange section 2311 and the connection section 2313 that are located closest to the bottom of the rack 11 in the heat exchange channel 231. In addition, in the server rack 10c, the rack 11 is not fully equipped with servers 12, and the servers 12 are concentrated in a lower half of the rack 11. In such a configuration, the bottom T-fitting 282 may be connected to the pump 40 via piping to receive low-temperature first coolant from the pump 40. Accordingly, the low-temperature first coolant entering the connection section 2313 and the heat exchange section 2311 located closest to the bottom of the rack 11 can directly dissipate heat from the heat concentration region. The middle T-fitting 283 may be connected to the heat exchanger 30 via piping to deliver high-temperature first coolant exiting the busbar 20 to the heat exchanger 30 for cooling. The top T-fitting 281 may be sealed and not connected to other components.

Similarly, in another embodiment, when the rack 11 of FIG. 10 are not fully equipped with the servers 12, and the servers 12 are concentrated in an upper half of the rack 11, the top T-fitting 281 may be connected to the pump 40 via piping to receive low-temperature first coolant from the pump 40, and the middle T-fitting 283 may be connected to the heat exchanger 30 via piping to deliver high-temperature first coolant exiting the busbar 20 to the heat exchanger 30 for cooling. The bottom T-fitting 282 may be sealed and not connected to other components.

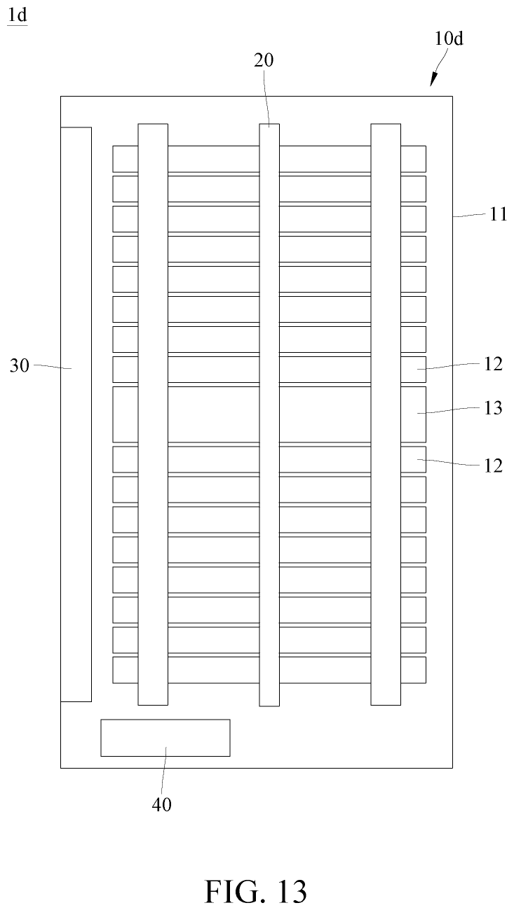

Referring to FIGS. 5 and 13, FIG. 13 is a rear view of a server system 1d according to some embodiments of the disclosure. The structural features of FIG. 13 may be applied to some other embodiments of the disclosure.

The busbar 20 according to the above embodiment may be applied to a configuration in a server rack 10d in which only one power module group 13 is located between the servers 12. The power module group 13 corresponds to two heat exchange sections 2311 and the connection section 2313 that are located farther from the top and the bottom of the rack 11 in the heat exchange channel 231. In such a configuration, the middle T-fitting 283 may be connected to the pump 40 via piping to receive low-temperature first coolant from the pump 40. Accordingly, the low-temperature first coolant entering the aforementioned two heat exchange sections 2311 and the connection section 2313 can directly dissipate heat from the heat concentration region. The top T-fitting 281 and the bottom T-fitting 282 may be connected to the heat exchanger 30 via piping to deliver high-temperature first coolant exiting the busbar 20 to the heat exchanger 30 for cooling.

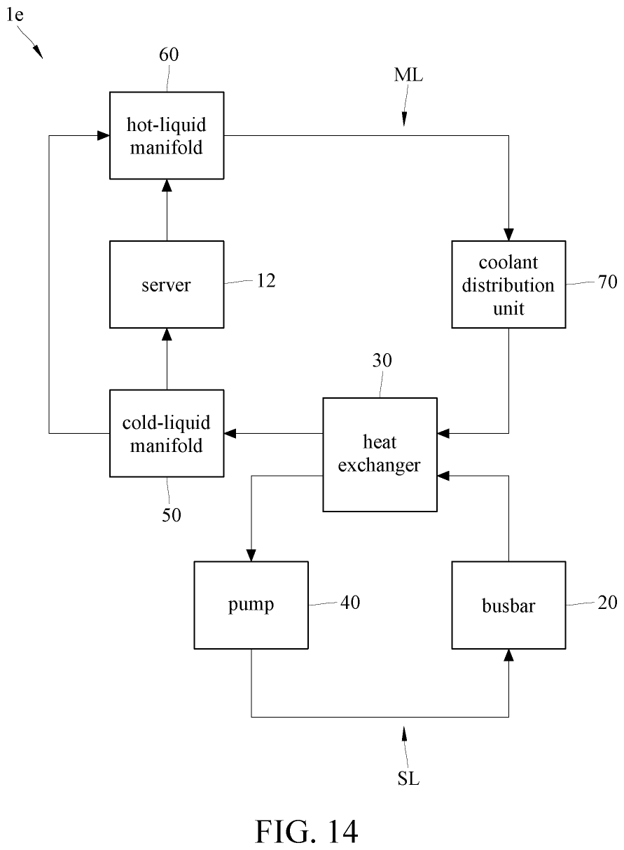

Then, referring to FIG. 14, FIG. 14 is a block diagram of a server system 1e according to some embodiments of the disclosure. The structural features of FIG. 14 may be applied to some other embodiments of the disclosure.

The server system 1e of the embodiment of FIG. 14 is similar to the server system 1 of the embodiment of FIG. 2. The differences therebetween are mainly described below, and identical portions will not be repeated.

In the server system 1e of the embodiment of FIG. 14, the heat exchanger 30 is in fluid communication with the cold-liquid manifold 50 and the coolant distribution unit 70, and the heat exchanger 30 is located upstream of the cold-liquid manifold 50 and downstream of the coolant distribution unit 70.

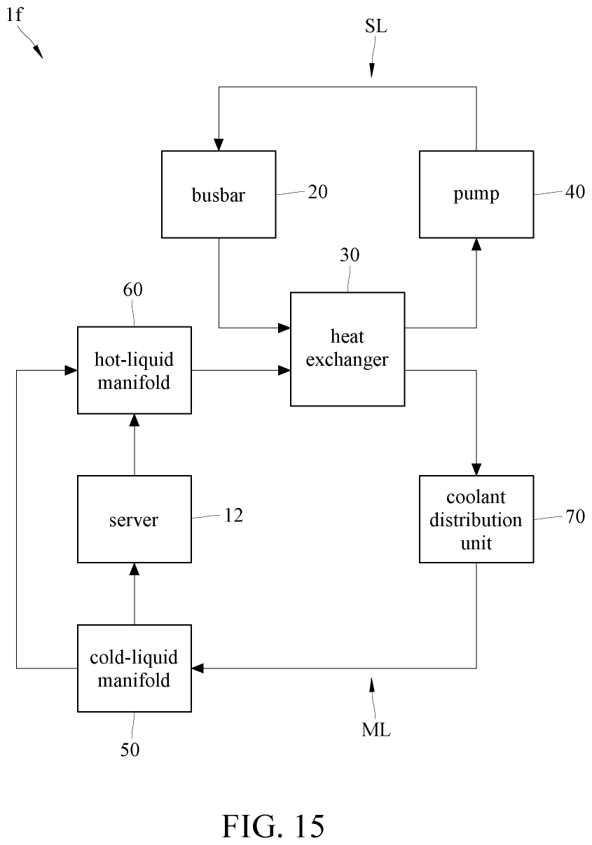

Then, referring to FIG. 15, FIG. 15 is a block diagram of a server system 1f according to some embodiments of the disclosure. The structural features of FIG. 15 may be applied to some other embodiments of the disclosure.

The server system 1f of the embodiment of FIG. 15 is similar to the server system 1 of the embodiment of FIG. 2. The differences therebetween are mainly described below, and identical portions will not be repeated.

In the server system 1f of the embodiment of FIG. 15, the heat exchanger 30 is in fluid communication with the hot-liquid manifold 60 and the coolant distribution unit 70, and the heat exchanger 30 is located downstream of the hot-liquid manifold 60 and upstream of the coolant distribution unit 70.

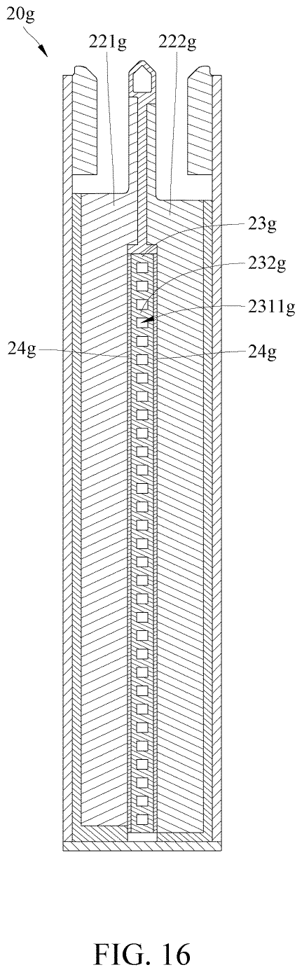

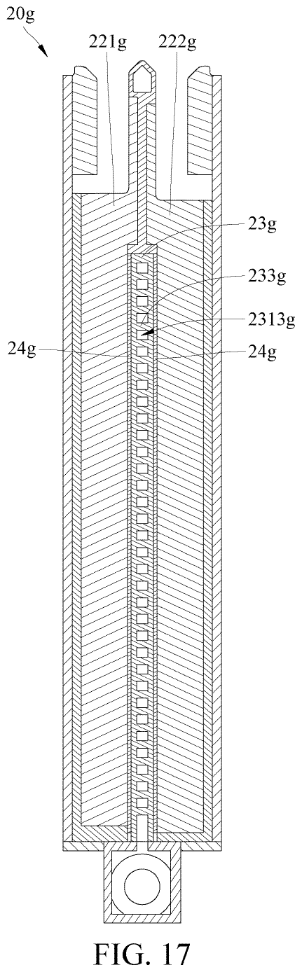

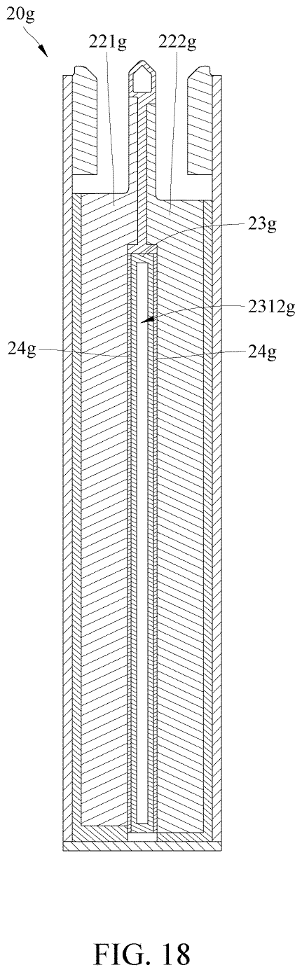

Then, referring to FIGS. 16 to 18, FIGS. 16 to 18 are cross-sectional views of a busbar 20g according to some embodiments of the disclosure, which are taken along the lines 7-7, 8-8 and 9-9 in FIG. 6, respectively. FIG. 16 illustrates a heat exchange section 2311g of a flow structure 23g of the busbar 20g and first fins 232g therein. FIG. 17 illustrates an connection section 2313g of the flow structure 23g of the busbar 20g and second fins 233g therein. FIG. 18 illustrates a transition section 2312g of the flow structure 23g of the busbar 20g in which no fin structures are provided. The structural features of FIGS. 16 to 18 may be applied to other embodiments of the disclosure.

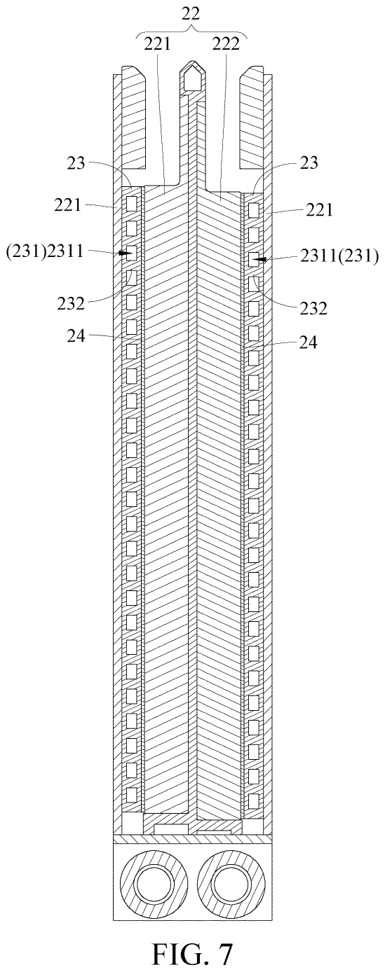

The busbar 20g of the embodiments of FIGS. 16 to 18 is similar to the busbar 20 of the embodiments of FIGS. 7 to 9. The differences therebetween are mainly described below, and identical portions will not be repeated.

In the embodiment of FIGS. 16 to 18, the busbar 20g includes a single flow structure 23g, and two opposite sides of the flow structure 23g are thermally coupled to a positive electrode 221g and a negative electrode 222g via two thermally conductive insulating materials 24g, respectively.

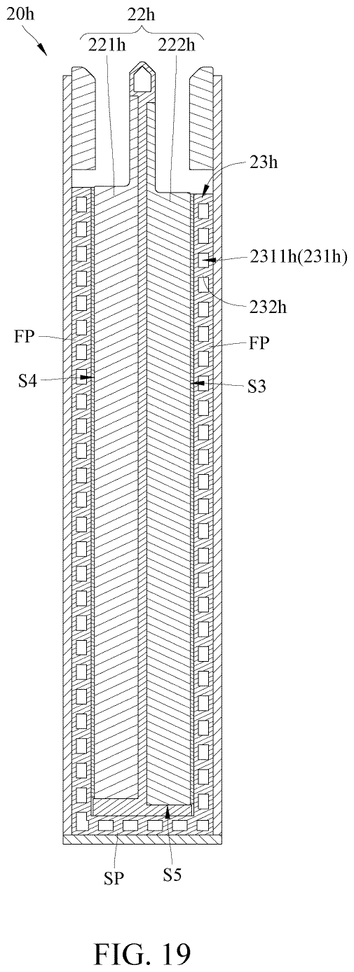

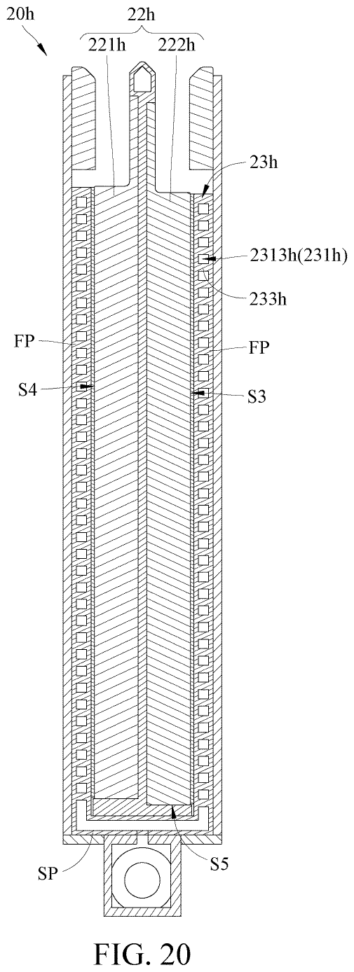

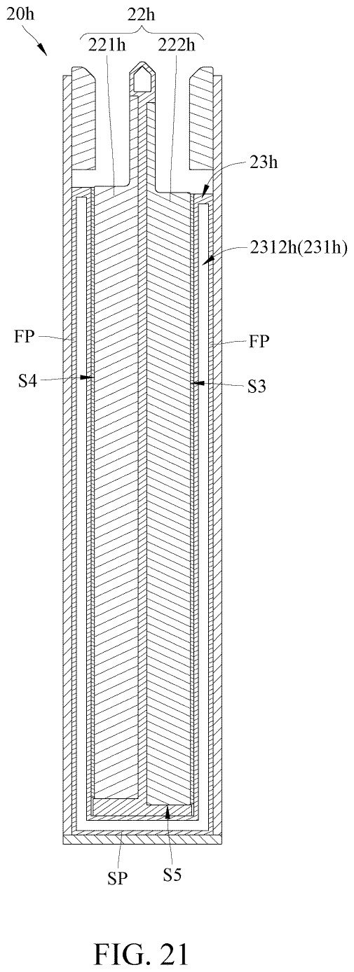

Then, referring to FIGS. 19 to 21, FIGS. 19 to 21 are cross-sectional views of a busbar 20h according to some embodiments of the disclosure, which are taken along the line 7-7, 8-8 and 9-9 in FIG. 6. FIG. 19 illustrates a heat exchange section 2311h of a flow structure 23h of the busbar 20h and first fins 232h therein. FIG. 20 illustrates a connection section 2313h of the flow structure 23h of the busbar 20h and second fins 233h therein. FIG. 21 illustrates a transition section 2312h of the flow structure 23h of the busbar 20h in which no fin structures are provided. The structural features of FIGS. 19 to 21 may be applied to other embodiments of the disclosure.

The busbar 20h of the embodiments of FIGS. 19 to 21 is similar to the busbar 20 of the embodiments of FIGS. 7 to 9. The differences therebetween are mainly described below, and identical portions will not be repeated.

In the embodiments of FIGS. 19 to 21, the busbar 20h includes a single flow structure 23h. The flow structure 23h may include two first portions FP and one second portion SP. The two first portions FP are thermally coupled to the electrode set 22h (i.e., a positive electrode 221h and a negative electrode 222h), and the second portion SP is connected to the two first portions FP. The heat exchange channel 231h is located in the two first portions FP and the second portion SP. In some embodiments, the two first portions FP and the second portion SP of the flow structure 23h may be integrally formed, or may be connected by other means, such as welding. In some embodiments, the two first portions FP and the second portion SP are respectively located on different sides S3, S4, S5 of the electrode set 22h, and the electrode set 22h is located between the two first portions FP.

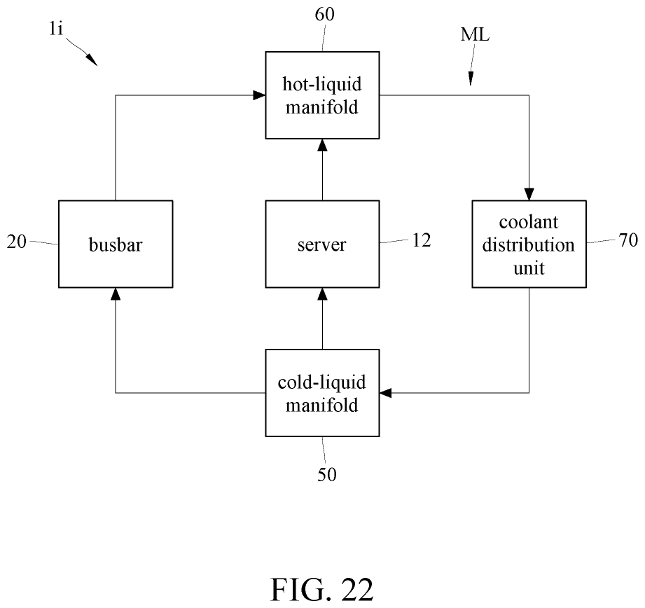

Then, referring to FIG. 22, FIG. 22 is a block diagram of a server system 1i according to some embodiments of the disclosure. The structural features of FIG. 22 may be applied to some other embodiments of the disclosure.

The server system 1i of the embodiment of FIG. 22 is similar to the server system 1 of the embodiment of FIG. 2. The differences therebetween are mainly described below, and identical portions will not be repeated.

In the server system 1i of the embodiment of FIG. 22, the server system 1i does not include a heat exchanger or a pump. The busbar 20 of the server system 1i is in fluid communication with the cold-liquid manifold 50 and the hot-liquid manifold 60, where the busbar 20 is located downstream of the cold-liquid manifold 50 and upstream of the hot-liquid manifold 60. In such a configuration, a conductive coolant in a primary cooling loop ML formed by the coolant distribution unit 70, the cold-liquid manifold 50, the server 12, and the hot-liquid manifold 60 may flow into the busbar 20 to dissipate heat from the busbar 20.

According to the busbar and the server system as discussed in the above embodiments, the flow structure of the busbar includes the heat exchange sections and the transition sections in fluid communication with each other, and the surface area-to-volume ratio of the heat exchange sections is greater than that of the transition sections. In such a configuration, regions of the flow structure requiring higher heat exchange efficiency may be handled by the heat exchange sections to improve heat exchange efficiency. Meanwhile, regions of the flow structure requiring lower heat exchange efficiency may be handled by the transition sections to reduce pressure drop. Accordingly, the pressure drop in the flow structure can be reduced while maintaining the required heat dissipation performance.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A server system, comprising:
a server rack, comprising a rack, at least one server and at least one power module group, wherein the at least one server and the at least one power module group are accommodated in the rack; and
a busbar, electrically connected to the at least one server and the at least one power module group, wherein the busbar comprises:
a casing;
an electrode set, disposed in the casing; and
at least one flow structure, disposed in the casing and thermally coupled to the electrode set, wherein the at least one flow structure is provided with a heat exchange channel, the heat exchange channel comprises at least one heat exchange section and at least one transition section in fluid communication with each other, and a surface area-to-volume ratio of the at least one heat exchange section is greater than a surface area-to-volume ratio of the at least one transition section.

2. The server system according to claim 1, wherein the at least one flow structure is further provided with a plurality of first fins, and the plurality of first fins are disposed only in the at least one heat exchange section.

3. The server system according to claim 2, wherein the busbar further comprises at least one connector, the at least one flow structure is further provided with a plurality of second fins, the heat exchange channel further comprises at least one connection section, the at least one connection section is in fluid communication with the at least one heat exchange section and the at least one transition section, the plurality of second fins are disposed only in the at least one connection section, and the at least one connector is in fluid communication with the at least one connection section.

4. The server system according to claim 3, wherein the at least one heat exchange section comprises a plurality of heat exchange sections, the at least one connection section comprises a plurality of connection sections, the plurality of heat exchange sections are located between the plurality of connection sections, the at least one transition section are located between the plurality of heat exchange sections, the at least one connector comprises a plurality of connectors, and the plurality of connectors are respectively in fluid communication with the plurality of connection sections.

5. The server system according to claim 4, wherein the at least one transition section comprises two transition sections, the at least one connection section comprises three connection sections, the at least one heat exchange section comprises four heat exchange sections; among the three connection sections, two of the four heat exchange sections are located between adjacent two of the three connection sections, and one of the two transition sections is located between the two of the four heat exchange sections.

6. The server system according to claim 5, wherein the at least one power module group is located adjacent to a top or a bottom of the rack, and the at least one power module group corresponds to one of the four heat exchange sections of the heat exchange channel that is located closest to the top or the bottom of the rack.

7. The server system according to claim 6, wherein the at least one power module group comprises two power module groups, the at least one server is located between the two power module groups, the two power module groups are respectively located adjacent to the top and the bottom of the rack, and the two power module groups respectively correspond to two of the four heat exchange sections of the heat exchange channel that are located closest to the top and the bottom of the rack.

8. The server system according to claim 5, wherein the at least one server comprises a plurality of servers, the at least one power module group is located between the plurality of servers, the at least one power module group corresponds to two of the four heat exchange sections of the heat exchange channel that are located farther away from a top and a bottom of the rack.

9. The server system according to claim 1, further comprising a heat exchanger, a cold-liquid manifold and a hot-liquid manifold, wherein the heat exchanger is in fluid communication with the at least one flow structure to jointly form a secondary cooling loop, the cold-liquid manifold is configured to deliver a coolant to the at least one server, the hot-liquid manifold is configured to receive the coolant from the at least one server; the cold-liquid manifold, the hot-liquid manifold and the at least one server together form a primary cooling loop, and the primary cooling loop is independent of the secondary cooling loop.

10. The server system according to claim 9, wherein the cold-liquid manifold and the hot-liquid manifold are in fluid communication with the heat exchanger.

11. The server system according to claim 9, wherein the heat exchanger is in fluid communication with the cold-liquid manifold, and the heat exchanger is located upstream of the cold-liquid manifold.

12. The server system according to claim 9, wherein the heat exchanger is in fluid communication with the hot-liquid manifold, and the heat exchanger is located downstream of the hot-liquid manifold.

13. The server system according to claim 1, further comprising a cold-liquid manifold and a hot-liquid manifold, wherein the cold-liquid manifold is configured to deliver a coolant to the at least one server, the hot-liquid manifold is configured to receive the coolant from the at least one server; the cold-liquid manifold, the hot-liquid manifold and the at least one server together form a primary cooling loop, and the at least one flow structure is in fluid communication with the cold-liquid manifold and the hot-liquid manifold.

14. The server system according to claim 1, wherein the at least one flow structure comprises two first portions and a second portion, the two first portions are thermally coupled to the electrode set, the second portion is connected to the two first portions, and the heat exchange channel is located in the two first portions and the second portion.

15. The server system according to claim 14, wherein the two first portions and the second portion are respectively located at different sides of the electrode set, and the electrode set is located between the two first portions.

16. The server system according to claim 1, wherein the busbar further comprises a plurality of connectors, the at least one flow structure comprises two flow structures, the two flow structures are respectively thermally coupled to two opposite sides of the electrode set, the casing comprises two casing portions, the two casing portions are respectively located at sides of the two flow structures away from the electrode set, and the plurality of connectors are respectively disposed on the two flow structures.

17. The server system according to claim 16, wherein the busbar further comprises a plurality of T-fittings; the electrode set, the two flow structures and the two casing portions are plate-shaped and together form a multilayer structure, the plurality of connectors overlap with each other in a stacking direction of the multilayer structure, and two of the plurality of connectors that overlap with each other are connected to one of the plurality of T-fittings.

18. A busbar, comprising:
a casing;
an electrode set, disposed in the casing; and
at least one flow structure, disposed in the casing and thermally coupled to the electrode set, wherein the at least one flow structure is provided with a heat exchange channel, the heat exchange channel comprises at least one heat exchange section and at least one transition section in fluid communication with each other, and a surface area-to-volume ratio of the at least one heat exchange section is greater than a surface area-to-volume ratio of the at least one transition section.

19. The busbar according to claim 18, wherein the at least one flow structure comprises two flow structures, the two flow structures are respectively thermally coupled to two opposite sides of the electrode set.

20. The busbar according to claim 18, wherein the at least one flow structure comprises two first portions and a second portion, the two first portions are thermally coupled to the electrode set, the second portion is connected to the two first portions, and the heat exchange channel is located in the two first portions and the second portion.

21. The busbar according to claim 20, wherein the two first portions and the second portion are respectively located at different sides of the electrode set, and the electrode set is located between the two first portions.

22. The busbar according to claim 18, wherein the at least one flow structure is further provided with a plurality of first fins, and the plurality of first fins are disposed only in the at least one heat exchange section.

23. The busbar according to claim 22, further comprising at least one connector, wherein the at least one flow structure is further provided with a plurality of second fins, the heat exchange channel further comprises at least one connection section, the at least one connection section is in fluid communication with the at least one heat exchange section and the at least one transition section, the plurality of second fins are disposed only in the at least one connection section, and the at least one connector is in fluid communication with the at least one connection section.

24. The busbar according to claim 23, wherein the plurality of first fins are plate-shaped structures, the plurality of second fins are pin-fin structures, a direction in which the at least one connector is in fluid communication with the at least one connection section is perpendicular to an extension direction of the plurality of first fins.

25. The busbar according to claim 23, wherein the at least one heat exchange section comprises a plurality of heat exchange sections, the at least one connection section comprises a plurality of connection sections, the plurality of heat exchange sections are located between the plurality of connection sections, the at least one transition section are located between the plurality of heat exchange sections, the at least one connector comprises a plurality of connectors, and the plurality of connectors are respectively in fluid communication with the plurality of connection sections.

26. The busbar according to claim 25, wherein the at least one transition section comprises two transition sections, the at least one connection section comprises three connection sections, the at least one heat exchange section comprises four heat exchange sections; among the three connection sections, two of the four heat exchange sections are located between adjacent two of the three connection sections, and one of the two transition sections is located between the two of the four heat exchange sections.

27. The busbar according to claim 18, further comprising a plurality of connectors, wherein the at least one flow structure comprises two flow structures, the two flow structures are respectively thermally coupled to two opposite sides of the electrode set, the casing comprises two casing portions, the two casing portions are respectively located at sides of the two flow structures away from the electrode set, and the plurality of connectors are respectively disposed on the two flow structures.

28. The busbar according to claim 27, further comprising a plurality of T-fittings, wherein the electrode set, the two flow structures and the two casing portions are plate-shaped and together form a multilayer structure, the plurality of connectors overlap with each other in a stacking direction of the multilayer structure, and two of the plurality of connectors that overlap with each other are connected to one of the plurality of T-fittings.
